(19) United States
(12) Patent Application Publication
(10) Pub. No.: US 2016/0046746 A1
(43) Pub. Date: Feb. 18, 2016

(54) COPOLYMERS CONTAINING VINYLIDENE FLUORIDE AND TRIFLUOROETHYLENE

(71) Applicants: ARKEMA FRANCE, Colombes (FR); CENTRE NATIONAL DE LA RECHERCHE SCIENTIFIQUE, Paris Cedex 14 (FR); UNIVERSITE MONTPELLIER II, SCIENCES ET TECHNIQUES, Montpellier Cedex 05 (FR)

(72) Inventors: Bruno AMEDURI, Montpellier (FR); Ali ALAAEDDINE, Beyrouth (LB)

(73) Assignees: ARKEMA FRANCE, Colombes (FR); UNIVERSITE MONTPELLIER II, SCIENCES ET TECHNIQUES, Montpellier Cedex 05 (FR); CENTRE NATIONAL DE LA RECHERCHE SCIENTIFIQUE, Paris Cedex 14 (FR)

(21) Appl. No.: 14/782,124

(22) PCT Filed: Mar. 27, 2014
(86) PCT No.: PCT/FR2014/050721

§ 371 Date: Oct. 2, 2015

(30) Foreign Application Priority Data
Apr. 3, 2013 (FR) 1352981

(51) Int. Cl. C08F 214/22; C09D 127/16; H01L 41/193; C08J 5/18

(52) U.S. Cl. CPC C08F 214/22; C08J 5/18; C09D 127/16; H01L 41/193; C08J 2327/16

(57) ABSTRACT

The subject matter of the invention is a copolymer obtained by free-radical copolymerization of vinylidene fluoride with trifluoroethylene and of at least a third monomer, the third monomer having a molar mass greater than 0 g/mol and corresponding to the formula: in which R₁ is a hydrogen atom or a fluorine atom, and R₂ and R₃ are chosen, independently of one another, from Cl, F and CF₃, and the functional groups are selected from phosphonate, carboxylic acid, SO₂X (where X is F, OK, ONa or OH) or Si(OR)₃ (R being a methyl, ethyl or isopropyl group) groups. The invention also relates to a process for preparing this copolymer.

### FIELD OF THE INVENTION

The present invention relates to copolymers based on vinylidene fluoride (VDF), on trifluoroethylene (TrFE) and on at least one third monomer, and also to a process for the preparation of these copolymers.

### TECHNICAL BACKGROUND

Fluoropolymers represent a class of compounds having noteworthy properties for a large number of applications, from paint or special coatings to leaktight seals, via the intermediacy of optics, microelectronics and membrane technology. Among these fluoropolymers, copolymers are particularly advantageous due to their diversity, their morphology, their exceptional properties and their versatility.

The paper by Yagi et al. in Polymer Journal, 6, 429-436 (1979), describes a conventional copolymerization of vinylidene fluoride with trifluoroethylene. These copolymers exhibit particularly advantageous piezoelectric properties, as is discussed in the paper by Higashihata et al. in Ferroelectrics, 2, 85-92 (1981).

The papers by Wang et al. in Macromolecules, 39, 4268-4271 (2006), by Lu et al. in Macromolecules, 39, 6962-6968 (2006), by Lu et al. in J. Am. Chem. Soc., 128, 8120-8121 (2006), and by Zhang et al. in Macromolecules, 40, 783-785 (2007), describe a process for the preparation of terpolymers of vinylidene fluoride, of trifluoroethylene and of chlorotrifluoroethylene (CTFE) by a copolymerization of vinylidene fluoride with CTFE, followed by a reduction of the chlorine atoms of the CTFE units.

Furthermore, controlled radical copolymerization techniques, that is to say techniques which make it possible to obtain control of the molar mass and the polydispersity index of the polymers, have also been provided.

The document U.S. Pat. No. 6,355,749 describes the preparation of terpolymers of vinylidene fluoride, of trifluoroethylene and of a comonomer, such as CTFE or HFP, according to a process of copolymerization controlled by means of borane compounds in the presence of oxygen. Likewise, the paper by Chung et al. in Macromolecules, 35, 7678-7684 (2002), describes the manufacture of terpolymers of vinylidene fluoride, of trifluoroethylene and of a chlorinated comonomer (CTFE, CDFE or 2-chloro-1,1-trifluoroethylene, VC or vinyl chloride, CFE or 1,1-chlorofluoroethylene), also according to a copolymerization controlled by means of borane compounds. A fluorinated comonomer (VF or vinyl fluoride, HFP) is also used by way of reference. This technique is difficult to carry out in practice due to the high cost of the borane compounds and the risks of explosion which they bring about.

Other methods of controlled radical copolymerization are based on the use of xanthate compounds as chain-transfer agents, under the name MADIX, for “Macromolecular Design via Interchange of Xanthates”, or also by means of iodine compounds as chain-transfer agents.

Two reviews summarizing relevant studies in the field have been published in Macromolecules, 43, 10163-10184 (2010), and in Chem. Rev., 109, 6632-6686 (2009).

The document US 2008/0081195 describes terpolymers, such as P(VDF-TrFE-CTFE) terpolymers, exhibiting two functional endings and prepared by polymerization controlled by borane or diiodine transfer agents.

The paper by Li et al. in J. Appl. Polym. Sci., 122, 3007-3015 (2011), describes the synthesis and the crystallization of P(VDF-TrFE-CTFE) terpolymers.

The paper by Saint Loup et al. in Macromolecules, 35, 1524-1536 (2002), describes the copolymerization of VDF and HFP and also the terpolymerization of VDF, HFP and CTFE initiated by hydrogen peroxide.

The properties of P(VDF-TrFE-CFE) and P(VDF-TrFE-CTFE) terpolymers are explored in the papers by Xu et al. in Appl. Phys. Lett., 78, 2360-2362 (2001), by Jeong et al. in Appl. Phys. Lett., 85, 4857-4859 (2004), by Claude et al. in Appl. Phys. Lett., 91, 212904 (2007), and by Claude et al. in Chem. Mater., 20, 2078-2080 (2008).

The paper by Zhu et al. in Macromolecules, 45, 2937-2954 (2012), describes the ferroelectric properties of several polymers of the polyvinylidene fluoride (PVDF) family and in particular of P(VDF-TrFE-CDFE), P(VDF-TrFE-CTFE), P(VDF-TrFE-HFP) and P(VDF-TrFE-CFE) terpolymers.

However, there still exists a need to develop novel fluorinated copolymers and in particular novel copolymers based on VDF and on TrFE.

### SUMMARY OF THE INVENTION

The invention relates first to a copolymer obtained by copolymerization of vinylidene fluoride, of trifluoroethylene and of at least one third monomer, said third monomer having a molar mass of greater than 100 g/mol and corresponding to the formula:

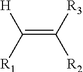

in which R₁ represents a hydrogen atom or a fluorine atom and R₂ and R₃ are chosen, independently of one another, from Cl, F, CF₃ and functional groups selected from phosphonate, carboxylic acid, SO₂X (where X represents F, OK, ONa or OH) or Si(OR)₃ (R representing a methyl, ethyl or isopropyl group) groups.

According to one embodiment, the third monomer is chosen from 2,3,3,3-tetrafluoropropene, 2-chloro-3,3,3-trifluoropropene, α,β-difluoroacrylic acid, 2-(trifluoro)methacrylic acid, dimethyl vinylphosphonate, bromotrifluoroethylene, vinyl trifluoroacetate, itaconic acid and t-butyl 2-(trifluoromethyl)acrylate.

According to one embodiment:
the molar proportion of units resulting from the vinylidene fluoride monomer is from 40 to 90% and preferably from 55 to 80%;
the molar proportion of units resulting from the trifluoroethylene monomer is from 5 to 50% and preferably from 10 to 40%; and
the molar proportion of units resulting from at least one third monomer is from 1 to 20% and preferably from 2 to 18%.

Another subject matter of the invention is a process for the preparation of a copolymer comprising a stage of copolymerization of a reaction mixture of vinylidene fluoride, of trifluoroethylene and of at least one third monomer having a molar mass of greater than 100 g/mol, the third monomer corresponding to the formula:

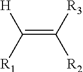

in which R₁ represents a hydrogen atom or a fluorine atom and R₂ and R₃ are chosen, independently of one another, from Cl, F, CF₃ and functional groups selected from phosphonate, carboxylic acid, SO₂X (where X represents F, OK, ONa or OH) or Si(OR)₃ (R representing a methyl, ethyl or isopropyl group) groups.

According to one embodiment, the third monomer is chosen from 2,3,3,3-tetrafluoropropene (or 1234yf), 2-chloro-3,3,3-trifluoropropene, α,β-difluoroacrylic acid, 2-(trifluoro)methacrylic acid, dimethyl vinylphosphonate, bromotrifluoroethylene, vinyl trifluoroacetate, itaconic acid and t-butyl 2-(trifluoromethyl)acrylate.

According to one embodiment:
the molar proportion of vinylidene fluoride in the reaction mixture is from 40 to 90% and preferably from 55 to 80%;
the molar proportion of trifluoroethylene in the reaction mixture is from 5 to 50% and preferably from 10 to 40%; and
the molar proportion of the third monomer(s) in the reaction mixture is from 1 to 20% and preferably from 2 to 18%;

the molar proportions being with respect to the sum of the vinylidene fluoride, trifluoroethylene and third monomer.

According to one embodiment, the reaction mixture is devoid of chain-transfer agent.

According to one embodiment, the reaction mixture essentially comprises and preferably consists of a mixture of vinylidene fluoride, of trifluoroethylene, of at least one third monomer, of radical initiator and of solvent and/or of water.

According to one embodiment, the reaction mixture is heated up to a temperature for initiation of reaction of between 60 and 90° C., preferably between 70 and 80° C. and more preferably between 72 and 76° C.

According to one embodiment, the copolymer described above is prepared by the abovementioned process.

Another subject matter of the invention is a film or a membrane comprising at least one copolymer as described above.

Another subject matter of the invention is a piezoelectric device comprising such a film.

Another subject matter of the invention is a ferroelectric device comprising such a film.

Another subject matter of the invention is a pyroelectric device comprising such a film.

Another subject matter of the invention is a coating comprising such a film.

The present invention makes it possible to meet the needs existing in the state of the art.

The invention is of particular use for the manufacture of piezoelectric, ferroelectric or pyroelectric compounds.

### BRIEF DESCRIPTION OF THE FIGURES

FIG. 1a represents a ¹H NMR spectrum in d₆-acetone (20° C., 400 MHz) of a poly(VDF-ter-TrFE-ter-1234yf) terpolymer (see example 1).

FIG. 1b represents a ¹⁹F NMR spectrum of the same terpolymer in d₆-acetone (20° C., 400 MHz).

FIG. 2a represents a ¹H NMR spectrum in d₆-acetone (20° C., 400 MHz) of a poly(VDF-ter-TrFE-ter-1234yf) terpolymer (see example 2).

FIG. 2b represents a ¹⁹F NMR spectrum of the same terpolymer in d₆-acetone (20° C., 400 MHz).

FIG. 3a represents a ¹H NMR spectrum in d₆-acetone (20° C., 400 MHz) of a poly(VDF-ter-TrFE-ter-1234yf) terpolymer (see example 3).

FIG. 3b represents a ¹⁹F NMR spectrum of the same terpolymer in d₆-acetone (20° C., 400 MHz).

FIG. 4a represents a ¹H NMR spectrum in d₆-acetone (20° C., 400 MHz) of a poly(VDF-ter-TrFE-ter-1234yf) terpolymer (see example 4).

FIG. 4b represents a ¹⁹F NMR spectrum of the same terpolymer in d₆-acetone (20° C., 400 MHz).

FIG. 5a represents a ¹H NMR spectrum in d₆-acetone (20° C., 400 MHz) of a poly(VDF-ter-TrFE-ter-1234yf) terpolymer (see example 5).

FIG. 5b represents a ¹⁹F NMR spectrum of the same terpolymer in d₆-acetone (20° C., 400 MHz).

FIG. 6a represents a ¹H NMR spectrum in d₆-acetone (20° C., 400 MHz) of a poly(VDF-ter-TrFE-ter-2-chloro-3,3,3-trifluoropropene) terpolymer (see example 6).

FIG. 6b represents a ¹⁹F NMR spectrum of the same terpolymer in d₆-acetone (20° C., 400 MHz).

FIG. 7a represents a ¹H NMR spectrum in d₆-acetone (20° C., 400 MHz) of a poly(VDF-ter-TrFE-ter-dimethyl vinylphosphonate) terpolymer (see example 7).

FIG. 7b represents a ¹⁹F NMR spectrum of the same terpolymer in d₆-acetone (20° C., 400 MHz).

FIG. 8a represents a ¹H NMR spectrum in d₆-acetone (20° C., 400 MHz) of a poly(VDF-ter-TrFE-ter-itaconic acid) terpolymer (see example 8).

FIG. 8b represents a ¹⁹F NMR spectrum of the same terpolymer in d₆-acetone (20° C., 400 MHz).

FIG. 9a represents a ¹H NMR spectrum in d₆-acetone (20° C., 400 MHz) of a poly(VDF-ter-TrFE-ter-α,β-difluoroacrylic acid) terpolymer (see example 9).

FIG. 9b represents a ¹⁹F NMR spectrum of the same terpolymer in d₆-acetone (20° C., 400 MHz).

### DESCRIPTION OF EMBODIMENTS OF THE INVENTION

The invention is now described in more detail and without implied limitation in the description which follows.

The invention provides for the preparation of a copolymer by means of a polymerization reaction between TrFE, VDF and at least one third monomer.

The term “copolymer” means here a polymer resulting from the copolymerization of at least three types of comonomers which are chemically different. The third monomer, which is distinct from TrFE and VDF, exhibits a molar mass of greater than 100 g/mol and corresponds to the formula:

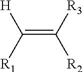

in which R₁ represents a hydrogen atom or a fluorine atom and R₂ and R₃ are chosen, independently from one another, from Cl, F, CF₃ and functional groups selected from phosphonate, carboxylic acid, SO₂X (where X represents F, OK, ONa or OH) or Si(OR)₃ (R representing a methyl, ethyl or isopropyl group) groups. “Functional group” is understood here to mean a group of atoms comprising at least two atoms, at least one of which is other than C and H.

According to one embodiment, the copolymers of the invention are terpolymers consisting of three different comonomers.

According to another embodiment, the copolymer of the invention is composed of four comonomers having distinct structures.

The copolymers according to the invention are random and linear.

Preferably, the third monomer exhibits a molar mass of less than or equal to 150 g/mol and in particular less than or equal to 145 g/mol or less than or equal to 140 g/mol.

According to one embodiment, the third monomer is chosen from 2,3,3,3-tetrafluoropropene (or 1234yf), 2-chloro-3,3,3-trifluoropropene, α,β-difluoroacrylic acid, 2-(trifluoro)methacrylic acid, dimethyl vinylphosphonate, bromotrifluoroethylene, vinyl trifluoroacetate, itaconic acid and t-butyl 2-(trifluoromethyl)acrylate.

The polymerization reaction is preferably conventional, in contrast to a controlled radical polymerization, that is to say that the polymerization is carried out without a chain-transfer agent.

“Chain-transfer agent” is understood to mean a substance capable of causing a chain transfer in the polymerization reaction. A chain transfer is a transfer of the reactive radical at the end of the growing polymer chain to another molecule. Xanthate, iodine or borane compounds are examples of chain-transfer agents. Reference may be made to the work by Améduri and Boutevin entitled Well Architectured Fluoropolymers: Synthesis, Properties and Applications, published by Elsevier, Amsterdam (2004).

The conventional polymerization reaction makes it possible in particular to obtain larger polydispersity indices than controlled radical polymerization.

The polymerization reaction is carried out in the presence of a radical initiator. The latter can, for example, be tert-butyl peroxypivalate (or TBPPI), tert-amyl peroxypivalate, bis(4-(tert-butyl)cyclohexyl)peroxydicarbonate, sodium, ammonium or potassium persulfate, benzoyl peroxide, tert-butyl hydroperoxide, tert-butyl peroxide or 2,5-bis(tert-butylperoxy)-2,5-dimethylhexane.

The reaction is carried out in a solvent which is, for example, chosen from 1,1,1,3,3-pentafluorobutane, acetonitrile, methyl ethyl ketone, dimethyl carbonate, 2,2,2-trifluoroethanol, hexafluoroisopropanol, methyl acetate, ethyl acetate, cyclohexanone, water and the mixtures of these.

The reaction is preferably carried out at a temperature of 10 to 200° C., preferably of 35 to 170° C., and at a pressure of 10 to 120 bar, preferably of 20 to 80 bar. The choice of the optimum temperature depends on the initiator which is used. Generally, the reaction is carried out for at least 6 hours, at a temperature at which the half-life of the initiator is approximately 1 hour.

A reaction temperature of between 60 and 90° C., preferably between 70 and 80° C. and more particularly between 72 and 76° C. is appropriate in some embodiments.

According to a preferred embodiment, the molar proportion of VDF units in the terpolymer is from 40 to 90%, preferably from 55 to 80%.

According to a preferred embodiment, the molar proportion of TrFE units in the terpolymer is from 5 to 50%, preferably from 10 to 40%.

According to a preferred embodiment, the molar proportion of units resulting from the third monomer in the terpolymer is from 1 to 20%, preferably from 2 to 18%.

The molar mass of the terpolymer obtained is preferably from 20 000 to 100 000 g/mol, more preferably from 20 000 to 80 000 g/mol. The higher the molar mass, the better are the properties of the materials obtained.

The polydispersity index of the terpolymer obtained is preferably from 1.4 to 3.5, more preferably from 1.48 to 2.5.

The copolymers obtained according to the invention are of use in particular in the manufacture of electrolytes or in the manufacture of membranes. They are also of use in the manufacture of piezoelectric, ferroelectric or pyroelectric devices and also of coatings.

### EXAMPLES

The following examples illustrate the invention without limiting it.

### Example 1

### Synthesis of poly(VDF-ter-TrFE-ter-1234yf) (VDF: 80%; TrFE: 15%; 1234yf: 5%—Initial Molar Ratios)

The synthesis of the polymer poly(VDF-ter-TrFE-ter-1234yf) is carried 2 0 out according to the following scheme:

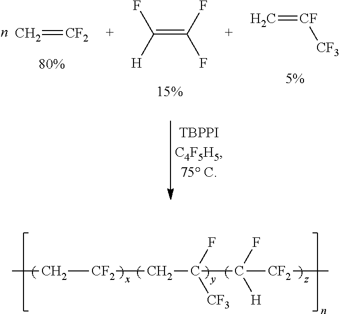

The radical polymerization is carried out in a 100 ml Parr Hastelloy autoclave equipped with a manometer, a bursting disc and valves for introducing gas and releasing. A regulated electronic device controls both the stirring and the heating of the autoclave. The reactor is pressurized to 30 bar of nitrogen for 1 h in order to confirm the leaktightness thereof.

Once the nitrogen has been discharged, the reactor is placed under vacuum for 40 min and then the radical initiator (TBPPI, 0.589 g, i.e. 3.38 mmol) and the solvent (60 ml of 1,1,1,3,3-pentafluorobutane) are introduced. The reactor is subsequently cooled to −60° C. (acetone/liquid nitrogen mixture) and then the 1234yf (1.5 g, i.e. 0.02 mol), the TrFE (3 g, i.e. 0.038 mol) and the VDF (13.0 g, i.e. 0.203 mol) are successively introduced therein.

The reactor is gradually heated to 74° C. and the change in the pressure and in the temperature are recorded. During the polymerization, an increase in the pressure inside the reactor is observed, due to the exothermicity of the reaction, and then a decrease in the pressure is observed, brought about by the conversion of the gaseous fluorinated monomers to give the desired terpolymer. At 74° C., the pressure is close to 34 bar (a rapid increase in the temperature after 78° C. is observed). During the hour which follows this exotherm, the pressure changes from 34 bar to 12 bar with a temperature maintained at 74° C.

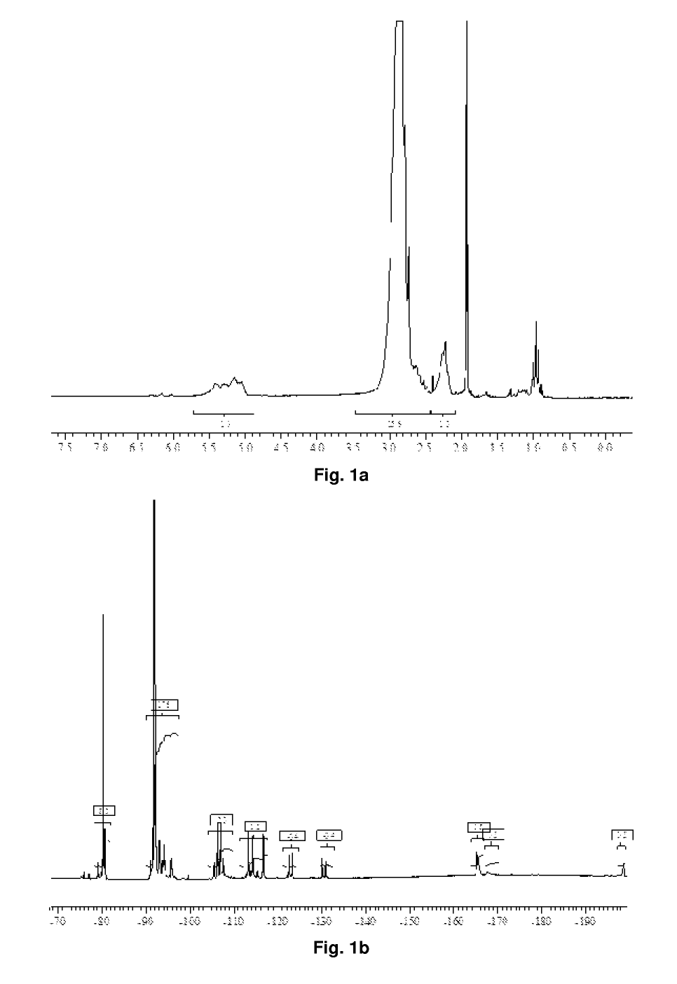

After reaction and cooling, the reactor is left in ice for 30 min and then vented (which makes possible the release of the unreacted fluorinated monomers). After opening the reactor, the solvent is removed by distillation and then the product is precipitated from cold pentane, filtered off, redissolved in the minimum amount of acetone, reprecipitated, filtered off and dried under vacuum (10⁻² bar, 60° C.) to constant weight. The poly(VDF-ter-TrFE-ter-1234yf) terpolymer, in the form of a white powder, is characterized by ¹H NMR spectroscopy (FIG. 1a) and ¹⁹F NMR spectroscopy (FIG. 1b). The yield by weight (weight of terpolymer collected/sum of the weights of the comonomers introduced into the reactor) is 62%.

### Example 2

### Synthesis of poly(VDF-ter-TrFE-ter-1234yf) (VDF: 70%; TrFE: 25%; 1234yf: 5%—Initial Molar Ratios)

The synthesis of the poly(VDF-ter-TrFE-ter-1234yf) polymer is carried out according to the same protocol as in example 1.

In detail, the operation is carried out as above in a 100 ml HC-276 reactor by respectively introducing therein the TBPPI (0.672 g, i.e. 3.86 mmol) and 60 ml of 1,1,1,3,3-pentafluorobutane. The reactor is subsequently cooled to −60° C. (acetone/liquid nitrogen mixture) and then the 1234yf (1.66 g, i.e. 0.014 mol) and the TrFE (5.94 g, i.e. 0.072 mol), followed by the VDF (13 g, i.e. 0.203 mol), are successively introduced therein.

The reactor is gradually heated to 74° C. and the changes in the pressure and in the temperature are recorded. During the polymerization, an increase in the pressure inside the reactor is observed and then a decrease in the pressure is observed, brought about by the conversion of the gaseous fluorinated monomers to give terpolymer. At 74° C., the pressure is close to 37 bar (exothermicity up to 76° C.). During the hour following this exotherm, the pressure falls to 13 bar for a temperature maintained at 74° C.

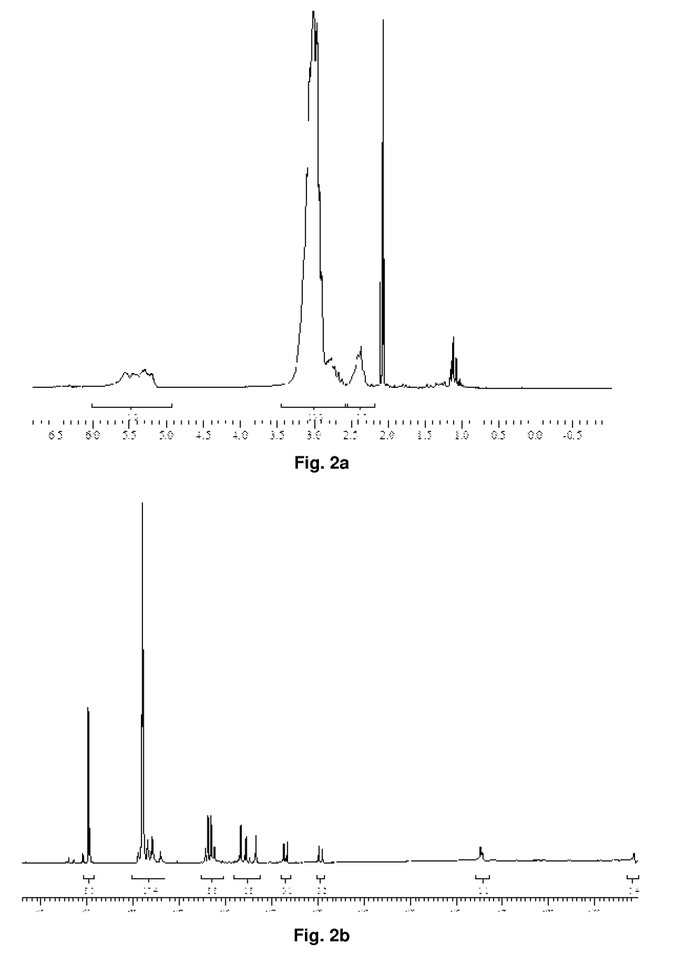

As above, after reaction and cooling, the reactor is left in ice for 30 min and then vented. After opening, the solvent is distilled off. The product is precipitated from cold pentane, filtered off and dried under vacuum (10⁻² bar, 60° C.) for 14 hours. The poly(VDF-ter-TrFE-ter-1234yf) terpolymer, in the form of a white powder, is characterized by ¹H NMR spectroscopy (FIG. 2a) and ¹⁹F NMR spectroscopy (FIG. 2b). The yield by weight is 88%.

### Example 3

### Synthesis of poly(VDF-ter-TrFE-ter-1234yf) (VDF: 57%; TrFE: 33%; 1234yf: 10%—Initial Molar Ratios)

The synthesis of the poly(VDF-ter-TrFE-ter-1234yf) polymer is carried out according to the same protocol as in example 1.

In detail, the operation is carried out as above in a 100 ml HC-276 reactor by respectively introducing therein the TBPPI (0.689 g, i.e. 5.48 mmol) and 60 ml of 1,1,1,3,3-pentafluorobutane. The reactor is subsequently cooled to −60° C. (acetone/liquid nitrogen mixture) and then the 1234yf (5 g, i.e. 0.043 mol) and the trifluoroethylene TrFE (11 g, i.e. 0.134 mol), followed by the VDF (15 g, i.e. 0.234 mol), are introduced therein.

The reactor is gradually heated to 74° C. and, during the polymerization, an increase in the pressure inside the reactor is observed, due to the exothermicity of the reaction, and then a decrease in the pressure is observed, brought about by the conversion of the gaseous fluorinated monomers to give the desired polymer. At 74° C., the pressure is close to 38 bar (exothermicity up to 76° C.). During the hour following this exotherm, the pressure falls to 17 bar for a temperature maintained at 74° C.

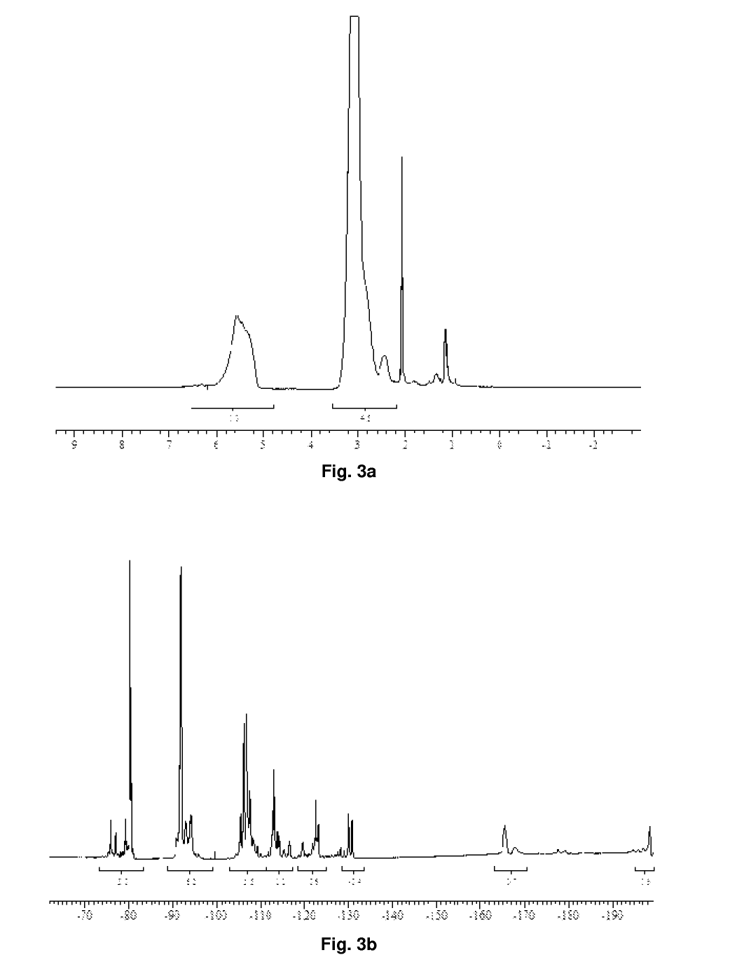

As above, after reaction and cooling, the reactor is left in ice for 30 min and then vented. After opening, the solvent is distilled off. The product is precipitated from cold pentane, filtered off, redissolved, reprecipitated and dried under vacuum (10⁻² bar, 60° C.) for 14 hours. The poly(VDF-ter-TrFE-ter-1234yf) terpolymer, in the form of a white powder, is characterized by ¹H NMR spectroscopy (FIG. 3a) and ¹⁹F NMR spectroscopy (FIG. 3b). The yield by weight is 58%.

### Example 4

### Synthesis of poly(VDF-ter-TrFE-ter-1234yf) (VDF: 60%; TrFE: 35%; 1234yf: 5%—Initial Molar Ratios)

The synthesis of the poly(VDF-ter-TrFE-ter-1234yf) polymer is carried out according to the same protocol as in example 1.

In detail, the operation is carried out as above in a 100 ml HC-276 reactor by respectively introducing therein the TBPPI (0.604 g, i.e. 3.47 mmol) and 60 ml of 1,1,1,3,3-pentafluorobutane. After cooling the reactor, the 1234yf (1.49 g, i.e. 0.013 mol), the TrFE (7.47 g, i.e. 0.091 mol) and then the VDF (10 g, i.e. 0.156 mol) are successively introduced therein.

As above, the reactor is heated to 74° C., showing an increase in the pressure inside the reactor and then a decrease in the pressure, related to the conversion of the gaseous fluorinated monomers to give the desired terpolymer. At 74° C., the pressure is close to 22 bar (exothermicity up to 76° C.). During the hour following this exotherm, the pressure falls to 8 bar for a temperature maintained at 74° C.

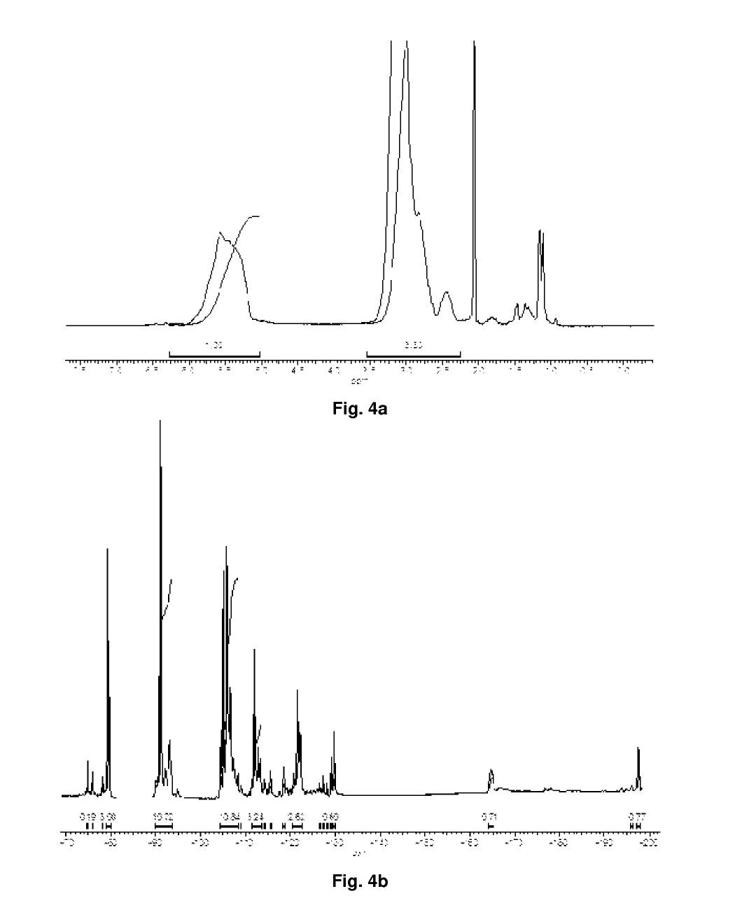

As above, after reaction and cooling, the reactor is left in ice for 30 min and then vented. After opening, the solvent is distilled off. The product is precipitated from cold pentane, filtered off and dried under vacuum (10⁻² bar, 60° C.) for 14 hours. The poly(VDF-ter-TrFE-ter-1234yf) terpolymer, in the form of a white powder, is characterized by ¹H NMR spectroscopy (FIG. 4a) and ¹⁹F NMR spectroscopy (FIG. 4b). The yield by weight is 72%.

### Example 5

### Synthesis of poly(VDF-ter-TrFE-ter-1234yf) (VDF: 58%; TrFE: 39%; 1234yf: 3%—Initial Molar Ratios)

The synthesis of the poly(VDF-ter-TrFE-ter-1234yf) polymer is carried out according to the same protocol as in example 1.

In detail, the operation is carried out as above in a 100 ml HC-276 reactor by respectively introducing therein the TBPPI (0.659 g, i.e. 3.78 mol) and 60 ml of 1,1,1,3,3-pentafluorobutane. The reactor is subsequently cooled and then the 1234yf (2 g, i.e. 0.017 mol) and the TrFE (16 g, i.e. 0.195 mol), followed by the VDF (10 g, i.e. 0.296 mol), are introduced therein.

The reactor is gradually heated to 74° C. and, during the polymerization, an increase in the pressure, which is close to 33 bar, is followed by a fall to 10 bar for a temperature maintained at 74° C. As above, after cooling, the reactor is cooled and then vented. After opening and distillation of the solvent, the terpolymer is precipitated from cold pentane, filtered off and dried under vacuum (10⁻² bar, 60° C.).

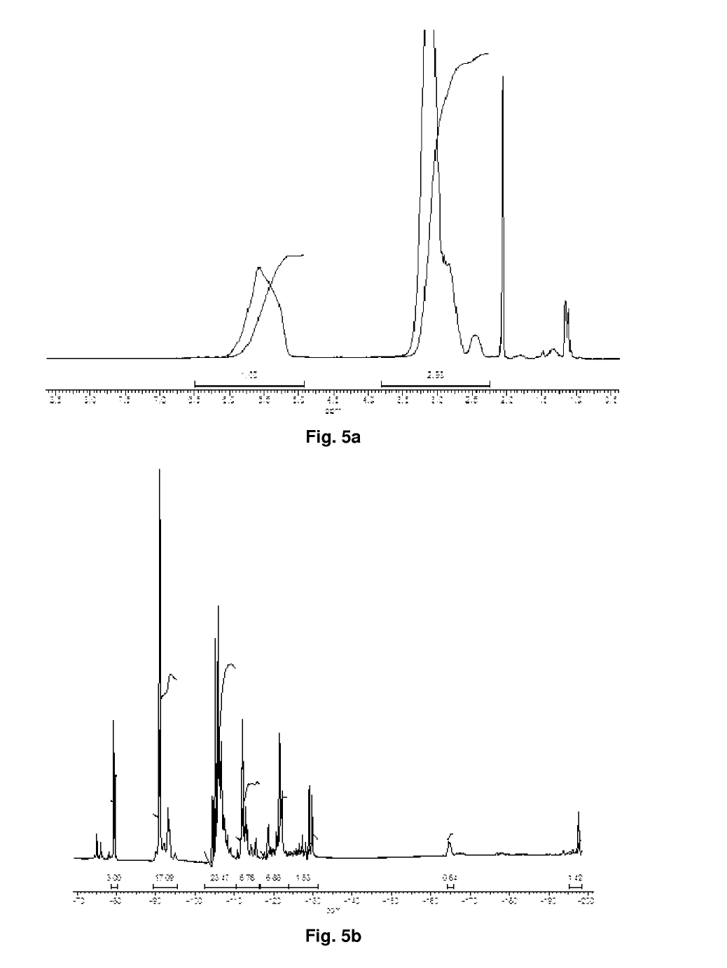

The poly(VDF-ter-TrFE-ter-1234yf) terpolymer, in the form of a white powder, is characterized by ¹H NMR spectroscopy (FIG. 5a) and ¹⁹F NMR spectroscopy (FIG. 5b). The yield is 69%.

### Example 6

### Synthesis of poly(VDF-ter-TrFE-ter-2-chloro-3,3,3-trifluoro-propene)terpolymer (VDF: 60%; TrFE: 35%; Comonomer: 5%—Initial Molar Ratios)

The synthesis of the poly(VDF-ter-TrFE-ter-2-chloro-3,3,3-trifluoropropene) polymer is carried out according to the following scheme:

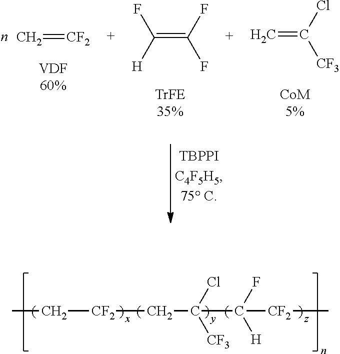

This polymerization is carried out as above in a 100 ml reactor by respectively introducing therein the TBPPI (0.604 g, i.e. 3.47 mol) and 60 ml of 1,1,1,3,3-pentafluorobutane. The reactor is subsequently cooled and then the 2-chloro-3,3,3-trifluoropropene (1.71 g, i.e. 0.013 mol) and the TrFE (7.47 g, i.e. 0.091 mol), followed by the VDF (10 g, i.e. 0.156 mol), are successively introduced therein.

The reactor is heated to 74° C. During the polymerization, an increase in pressure inside the reactor is observed (25 bar), followed by a decrease in the pressure (12 bar) for a temperature maintained at 74° C.

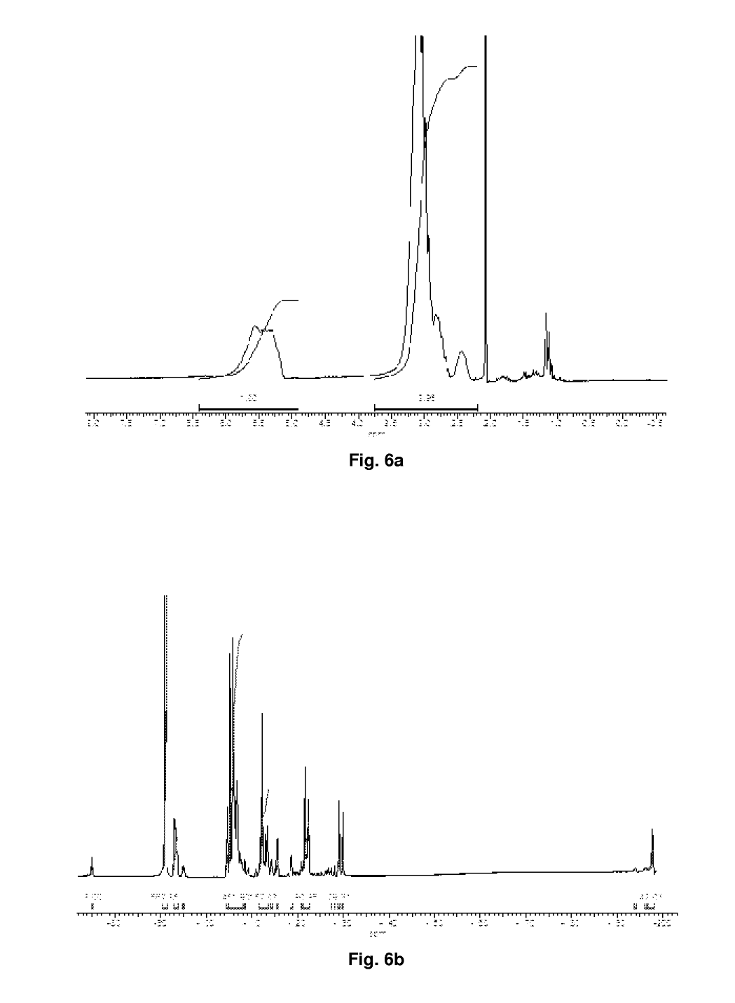

As above, after cooling the reactor is cooled, then vented and opened. The solvent is subsequently distilled off and then the terpolymer is precipitated from cold pentane, filtered off, redissolved, reprecipitated and dried under vacuum (10⁻² bar, 60° C.) for 14 hours. The poly(VDF-ter-TrFE-ter-coM) terpolymer, in the form of a white powder, is characterized by ¹H NMR spectroscopy (FIG. 6a) and ¹⁹F NMR spectroscopy (FIG. 6b). The yield by weight is 87%.

### Example 7

### Synthesis of poly(VDF-ter-TrFE-ter-dimethyl vinylphosphonate)terpolymer (VDF: 60%; TrFE: 35%; Comonomer: 5%—Initial Molar Ratios)

The synthesis of the poly(VDF-ter-TrFE-ter-dimethyl vinylphosphonate) polymer is carried out according to the following scheme:

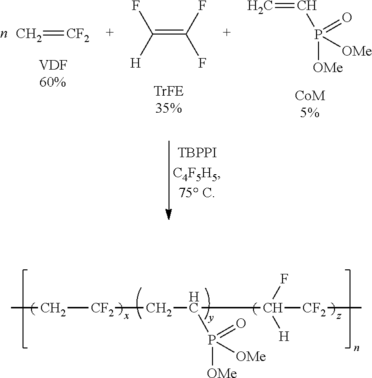

As in the preceding examples, a 100 ml HC-276 reactor is vented and placed under vacuum and TBPPI (0.604 g, i.e. 3.47 mol), dimethyl vinylphosphonate (1.76 g, i.e. 0.013 mol) and 60 ml of 1,1,1,3,3-pentafluorobutane are respectively introduced therein. The reactor is subsequently cooled and then the TrFE (7.47 g, i.e. 0.091 mol), followed by the VDF (10 g, i.e. 0.156 mol), are subsequently transferred therein.

The reactor is gradually heated to 74° C. During the polymerization, an increase in the pressure inside the reactor is observed (22 bar), followed by a decrease in the pressure (17 bar).

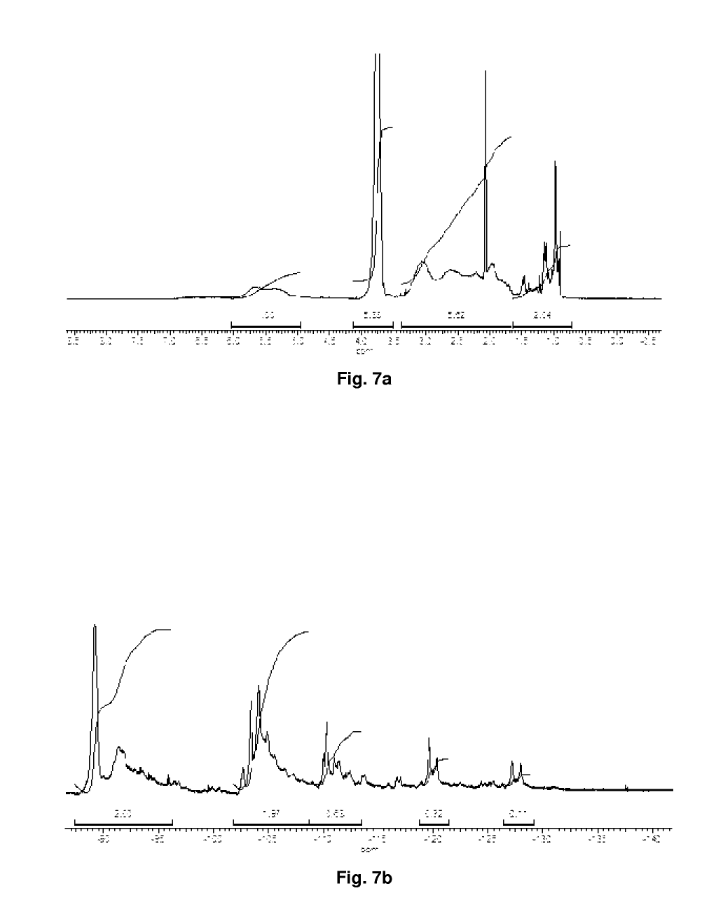

After reaction, the reactor is cooled, vented and then opened and the solvent is subsequently distilled off. The product is precipitated from cold pentane, filtered off and dried under vacuum (10⁻² bar, 60° C.) for 14 hours. The poly(VDF-ter-TrFE-ter-coM) terpolymer, in the form of a clear elastomer, is characterized by ¹H NMR spectroscopy (FIG. 7a) and ¹⁹F NMR spectroscopy (FIG. 7b). The yield by weight is 26%.

### Example 8

### Synthesis of poly(VDF-ter-TrFE-ter-itaconic acid) terpolymer (VDF: 60%; TrFE: 35%; Comonomer: 5%—Initial Molar Ratios)

The synthesis of the poly(VDF-ter-TrFE-ter-itaconic acid) polymer is carried out according to the following scheme:

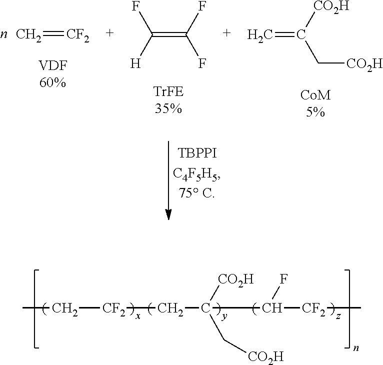

The TBPPI (0.604 g, i.e. 3.47 mol), the itaconic acid (1.69 g, i.e. 0.013 mol), 50 ml of 1,1,1,3,3-pentafluorobutane and 10 ml of distilled water are respectively introduced into a 100 ml HC-276 reactor. The reactor is subsequently cooled and then the TrFE (7.47 g, i.e. 0.091 mol) followed by the VDF (10 g, i.e. 0.156 mol), are transferred therein.

The reactor is gradually heated to 74° C. and an increase in the pressure to 25 bar, followed by a fall to 13 bar, is recorded.

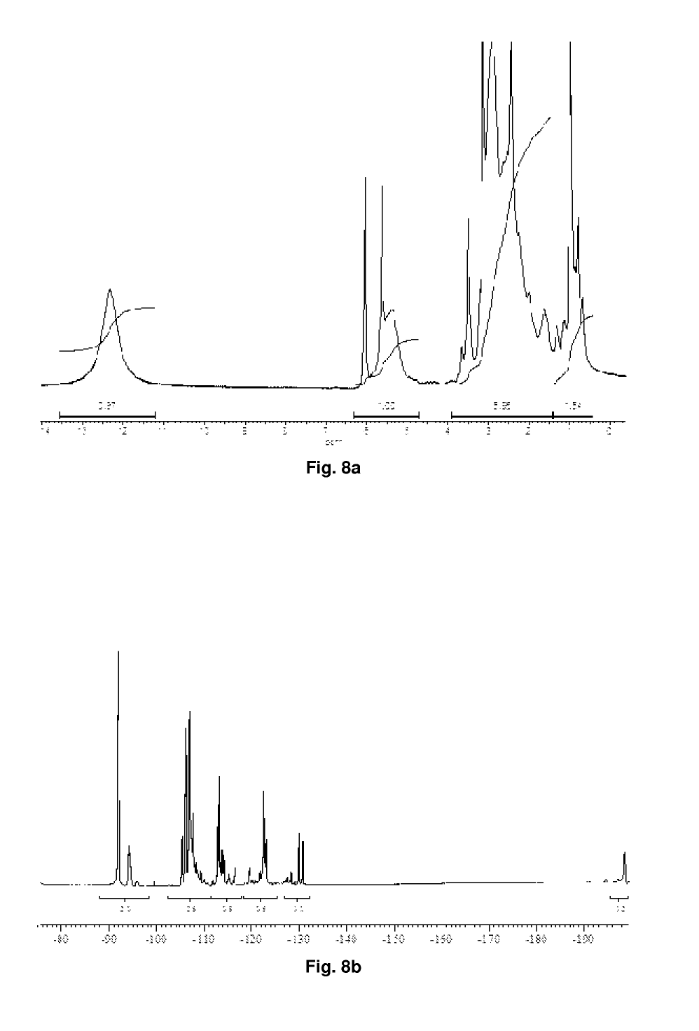

After reaction and cooling, the reactor is vented and then opened. The solvent is distilled off. The product is precipitated from cold pentane, filtered off and dried under vacuum (10⁻² bar, 60° C.) for 14 hours. The poly(VDF-ter-TrFE-ter-coM) polymer, in the form of an off-white elastomer, is characterized by ¹H NMR spectroscopy (FIG. 8a) and ¹⁹F NMR spectroscopy (FIG. 8b). The calculated yield is 44%.

### Example 9

### Synthesis of poly(VDF-ter-TrFE-ter-a,13-difluoroacrylic acid) terpolymer (VDF: 60%; TrFE: 35%; Comonomer: 5%—Initial Molar Ratios)

The synthesis of the poly(VDF-ter-TrFE-ter-α,β-difluoroacrylic acid) polymer is carried out according to the following scheme:

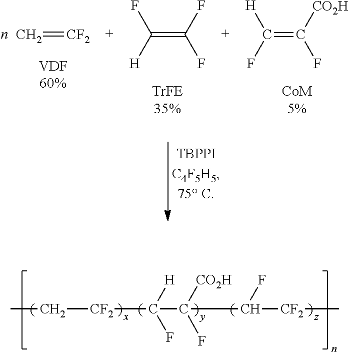

As above, a 100 ml HC-276 reactor is placed under vacuum and then the TBPPI (0.604 g, i.e. 3.47 mol), the α,β-difluoroacrylic acid (1.40 g, i.e. 0.013 mol) and 60 ml of 1,1,1,3,3-pentafluorobutane are respectively introduced. The reactor is subsequently cooled and then the TrFE (7.47 g, i.e. 0.091 mol), followed by the VDF (10 g, i.e. 0.156 mol), are successively introduced therein.

The reactor is gradually heated to 74° C. and an increase in the pressure is noted (26 bar), followed by a fall to 8 bar.

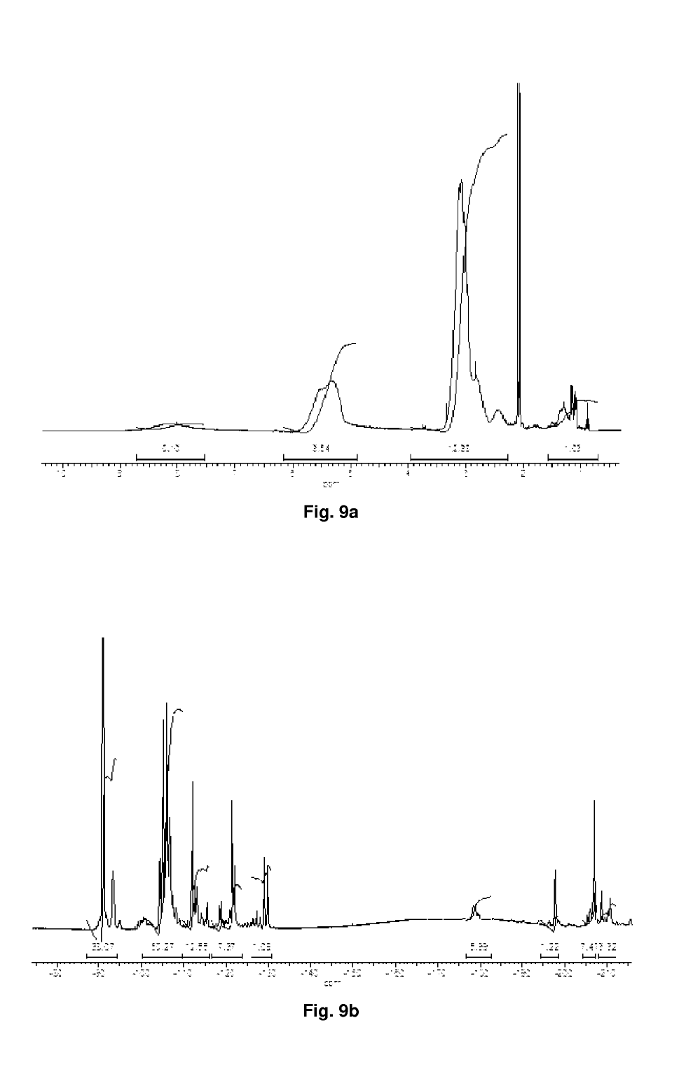

After reaction and cooling, the reactor is vented and then opened. The solvent is subsequently distilled off. The product is precipitated from cold pentane, filtered off and dried under vacuum (10⁻² bar, 60° C.) for 14 hours. The poly(VDF-ter-TrFE-ter-α,β-difluoroacrylic acid) terpolymer, in the form of an off-white elastomer, is characterized by ¹H NMR spectroscopy (FIG. 9a) and ¹⁹F NMR spectroscopy (FIG. 9b). The yield by weight is 79%.

The conditions and the results of the preceding syntheses are summarized in the following table:

| | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|
| VDF init. (%) | 80 | 70 | 57 | 60 | 58 | 60 | 60 | 60 | 60 |
| TrFE init. (%) | 15 | 25 | 33 | 35 | 39 | 35 | 35 | 35 | 35 |
| CoM init. (%) | 5 | 5 | 10 | 5 | 3 | 5 | 5 | 5 | 5 |
| VDF fin. (%) | 81 | 76 | 61 | 66 | 65 | 65 | 50 | 65 | 65 |
| TrFE fin. (%) | 10 | 16 | 23 | 27 | 30 | 33 | 32 | 25 | 30 |
| CoM fin. (%) | 9 | 8 | 16 | 7 | 5 | 2 | 18 | 10 | 5 |
| TBPPI (%) | 1 | 1 | 1 | 1 | 0.5 | 1 | 1 | 1 | 1 |
| Pₘₐₓ (bar) | 34 | 37 | 25 | 20 | 33 | 25 | 25 | 22 | 25 |
| ΔP (bar) | 22 | 24 | 16 | 15 | 23 | 13 | 3 | 5 | 13 |
| Yield (%) | 62 | 88 | 58 | 72 | 69 | 87 | 26 | 44 | 79 |
| Mₙ (g/mol) | 20 000 | 30 300 | 22 400 | 22 200 | 31 600 | 26 000 | 15 000 | nd | nd |
| PDI | 1.62 | 1.49 | 1.65 | 1.52 | 1.48 | 1.69 | 1.72 | nd | nd |
| Td_{10%} (° C.) | 403 | 406 | 391 | 380 | 389 | 390 | nd | nd | nd |
| T_{g} (° C.) | −40 | −25 | −15 | −39 | −19 | −22 | nd | nd | nd |
| Tₘ (° C.) | 111 | 106 | 41/109 | 36/105 | 28/116 | 54/127 | nd | nd | nd |
| T_{c} (° C.) | 86 | 93 | 28/94 | 24/87 | 25/97 | 39/110 | nd | nd | nd |

In this table, the three lines VDF init., TrFE init. and CoM init. give the molar composition of each of the monomers in the reaction mixture; the three lines VDF fin., TrFE fin. and CoM fin. give the molar composition of each of the units in the terpolymer synthesized; the line TBPPI gives the molar proportion of initiator used; the line Pₘₐₓ gives the maximum pressure reached in the reactor during the polymerization; the line ΔP gives the fall in pressure observed after the exotherm during the reaction; the line Yield gives the yield by weight obtained; the line Mₙ gives the number-average molar mass of the terpolymer, as determined by size exclusion chromatography with a polymethyl methacrylate standard; the line PDI gives the polydispersity index, as determined by the same method; the line Td_{10%} gives the decomposition temperature (10% weight loss) of the terpolymer, as determined by thermogravimetric analysis under air, at 10° C./min; the line T_{g} gives the glass transition temperature of the terpolymer, as determined by differential scanning calorimetry (DSC); the line Tₘ gives the melting temperature of the terpolymer, as determined by differential scanning calorimetry (DSC); and the line T_{c} gives the crystallization temperature of the terpolymer, as determined by differential scanning calorimetry (DSC).

1. A random linear copolymer obtained by copolymerization of vinylidene fluoride, of trifluoroethylene and of at least one third monomer, the third monomer having a molar mass of greater than 100 g/mol and corresponding to the formula: 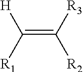
in which R₁ represents a hydrogen atom or a fluorine atom and R₂ and R₃ are chosen, independently of one another, from Cl, F, CF₃, phosphonate, carboxylic acid, SO₂X, where X represents F, OK, ONa or OH, or Si(OR)₃, R representing a methyl, ethyl or isopropyl group.

2. The copolymer as claimed in claim 1, in which the third monomer is chosen from 2,3,3,3-tetrafluoropropene, 2-chloro-3,3,3-trifluoropropene, α,β-difluoroacrylic acid, 2-(trifluoro)methacrylic acid, dimethyl vinylphosphonate, bromotrifluoroethylene, vinyl trifluoroacetate, itaconic acid and t-butyl 2-(trifluoromethyl)acrylate.

3. The copolymer as claimed in claim 1, in which:
the molar proportion of units resulting from the vinylidene fluoride monomer is from 40 to 90% and preferably from 55 to 80%;
the molar proportion of units resulting from the trifluoroethylene monomer is from 5 to 50% and preferably from 10 to 40%; and
the molar proportion of units resulting from the third monomer is from 1 to 20% and preferably from 2 to 18%.

4. A process for the preparation of a copolymer comprising a stage of copolymerization of a reaction mixture of vinylidene fluoride, of trifluoroethylene and of at least one third monomer having a molar mass of greater than 100 g/mol, the third monomer corresponding to the formula: 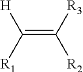
in which R₁ represents a hydrogen atom or a fluorine atom and R₂ and R₃ are chosen, independently of one another, from Cl, F, CF₃ and functional groups selected from phosphonate, carboxylic acid, SO₂X (where X represents F, OK, ONa or OH) or Si(OR)₃ (R representing a methyl, ethyl or isopropyl group) groups.

5. The process as claimed in claim 4, in which the third monomer is chosen from 2,3,3,3-tetrafluoropropene, 2-chloro-3,3,3-trifluoropropene, α,β-difluoroacrylic acid, 2-(trifluoro)methacrylic acid, dimethyl vinylphosphonate, bromotrifluoroethylene, vinyl trifluoroacetate, itaconic acid and t-butyl 2-(trifluoromethyl)acrylate.

6. The process as claimed in claim 4, in which:
the molar proportion of vinylidene fluoride in the reaction mixture is from 40 to 90% and preferably from 55 to 80%;
the molar proportion of trifluoroethylene in the reaction mixture is from 5 to 50% and preferably from 10 to 40%; and
the molar proportion of the third monomer in the reaction mixture is from 1 to 20% and preferably from 2 to 18%;
the molar proportions being with respect to the sum of the vinylidene fluoride, trifluoroethylene and third monomer.

7. The process as claimed in claim 4, in which the reaction mixture is devoid of chain-transfer agent.

8. The process as claimed in claim 4, in which the reaction mixture is essentially composed of and preferably consists of a mixture of vinylidene fluoride, of trifluoroethylene, of at least one third monomer, of radical initiator and of solvent and/or of water.

9. The process as claimed in claim 4, in which the reaction mixture is heated up to a temperature for initiation of reaction of between 60 and 90° C., preferably between 70 and 80° C. and more particularly between 72 and 76° C.

10. The copolymer prepared by the process of claim 4.

11. A film or membrane comprising at least one copolymer as claimed in claim 1.

12. A piezoelectric device comprising a film as claimed in claim 11.

13. A ferroelectric device comprising a film as claimed in claim 11.

14. A pyroelectric device comprising a film as claimed in claims 11.

15. A coating comprising a film as claimed in claim 11.
